(19) United States
(12) Patent Application Publication
(10) Pub. No.: US 2011/0247676 A1
(43) Pub. Date: Oct. 13, 2011

(54) Photonic Crystal Solar Cell

(75) Inventors: Jeffrey C. Grossman, Brookline, MA (US); Alexander K. Zettl, Kensington, CA (US)

(73) Assignee: The Regents of the University of California, Oakland, CA (US)

(21) Appl. No.: 13/121,667

(22) PCT Filed: Sep. 28, 2009
(86) PCT No.: PCT/US09/58544

§ 371 Date: Jun. 23, 2011

Related U.S. Application Data
(60) Provisional application No. 61/101,444, filed on Sep. 30, 2008.

(51) Int. Cl. H01L 31/02; H01L 31/042; H01L 31/18; H01L 31/0264

(52) U.S. Cl. 136/244; 136/252; 136/261; 136/260; 438/72; 257/E31.128

(57) ABSTRACT

The present invention provides a photovoltaic cell, which is contained within a photonic crystal structure. The photonic crystal is at least two-dimensional, and contains defects to guide incident light, e.g., sunlight, into a crystal cavity, where the concentrated light is guided into a cavity, preferably a photonic optical cavity, which is also a photovoltaic region comprising a semiconductor heterojunction for forming a photovoltaic current.

### CROSS-REFERENCE TO RELATED APPLICATIONS

This application claims priority from U.S. Provisional Patent Application No. 61/101,444, filed on Sep. 30, 2008, which is hereby incorporated by reference in its entirety.

### STATEMENT OF GOVERNMENTAL SUPPORT

This invention was made with U.S. Government support under Contract Number DE-AC02-05CH11231 between the U.S. Department of Energy and The Regents of the University of California for the management and operation of the Lawrence Berkeley National Laboratory. The U.S. Government has certain rights in this invention.

### REFERENCE TO SEQUENCE LISTING, COMPUTER PROGRAM, OR COMPACT DISK

None.

### BACKGROUND OF THE INVENTION

1. Technical Field

The present invention relates to the field of photonic crystals and their use in photovoltaic (solar) cells.

2. Related Art

Presented below is background information on certain aspects of the present invention as they may relate to technical features referred to in the detailed description, but not necessarily described in detail. That is, certain components of the present invention may be described in greater detail in the materials discussed below. The discussion below should not be construed as an admission as to the relevance of the information to the claimed invention or the prior art effect of the material described.

In conventional solar cells, light enters an antireflective layer and then a layer of silicon in which much of the light is converted into electricity. But some of the light reflects off an aluminum backing, returns through the silicon, and exits without generating electricity. To address this problem workers in the field have prepared or are attempting to prepare new materials that make it possible to convert more of this light into electricity. In some cases, these materials employ photonic crystals, which could be engineered to capture and recycle the photons that slip through thin layers of silicon. The photonic crystal is a two-dimensional or three-dimensional artificial crystal structure formed of a dielectric substance having a period of about the wavelength of light.

A photonic crystal can reflect light incident from any angle for frequencies and polarizations within the photonic band gap. Its origin is similar to that of the semiconductor band gap. In a periodic medium, waves must oscillate in a specific form, dictated by Bloch's theorem. When the waves, in this case photons, vary with a period commensurate with the period of the crystal, they can concentrate their energy either in low or high dielectric, giving rise to two different allowed energies. The energies between form the photonic band gap, a range of forbidden energies that are reflected at the surface. An additional advantage of the photonic crystal is that it can reflect light within the bandgap incident from any angle or medium, since the corresponding propagating modes are wholly forbidden. Second, wave optics-based devices can be designed to diffract incoming beams into highly oblique angles, according to Bragg's law. This applies both to gratings as well as photonic crystals, and in both cases, will depend primarily on the parameters of the device at the interface with homogeneous dielectric (e.g., the photovoltaic material).

Specific Patents and Publications

US 2005/0109390 to Shimomura, et al., published May 26, 2005, entitled “Photoelectric conversion device and solar cell comprising same,” discloses a high-efficiency photoelectric conversion device which comprises a photonic crystal consisting essentially of a photoelectric conversion substance, and a light-emitting dye contained inside the photonic crystal, and in which the photonic crystal has a periodic structure that retards the light emission by the light-emitting dye. The photonic crystal disclosed there has a periodic structure of around the wavelength of light. A light-emitting dye is incorporated inside a photonic crystal that does not transmit the light emitted by the dye therein, and the photonic crystal with the dye therein thus retards the light emission by the dye and, as a result, the light energy conversion efficiency of the device with the photonic crystal therein is thereby increased. Further as disclosed there, the photoelectric conversion substance which may be used includes, for example, titanium oxide, zinc oxide, strontium titanate, tin oxide, tungsten trioxide, dibismuth trioxide, ferric oxide, zirconia, etc.

Bermel et al. “Improving thin-film crystalline silicon solar cell efficiencies with photonic crystals,” Optics Express 15(25): 6986-17000 (10 Dec. 2007) discloses a photonic crystal-based light-trapping approach. For a solar cell made of a 2 μm thin film of c-Si and a 6 bilayer distributed Bragg reflector (DBR) in the back, power generation can be enhanced by a relative amount of 24.0% by adding a 1D grating, 26.3% by replacing the DBR with a six-period triangular photonic crystal made of air holes in silicon, 31.3% by a DBR plus 2D grating, and 26.5% by replacing it with an eight-period inverse opal photonic crystal. Instead of reflecting back out of the solar cell, the light is diffracted by one layer of the material. This causes the light to reenter the silicon at a low angle, at which point it bounces around until it is absorbed. The light that makes it through the first layer is reflected by the second layer of material (smaller dots) before being diffracted into the silicon.

Similarly, US 2007/0235072 by Bermel et al., published Oct. 11, 2007, entitled “Solar cell efficiencies through periodicity,” discloses a solar cell which includes a photovoltaic material region. The photovoltaic material region is covered by a uniform anti-reflection coating. A photonic crystal structure is positioned on the photovoltaic material region. The photonic crystal structure provides a medium to produce a plurality of spatial orientations of an incident light signal received by the solar cell so as to allow trapping of a selective frequency of incident light in the solar cell.

U.S. Pat. No. 7,333,705 to Hyde, issued Feb. 19, 2008, entitled “Photonic crystal energy converter,” discloses a photonic crystal which is configured with wavelength converting material to act as a concentrator for electromagnetic energy. The concentrator may also be configured with energy conversion devices to convert the electromagnetic energy into another form of energy. This patent discloses a photonic crystal formed by patterning holes in a dielectric material, and, further, that many other ways of fabricating photonic crystals are known to those in the art, including ways of making fully three-dimensional photonic crystals having a band-gap in three dimensions.

One such method is described in Divliansky, et al., “Fabrication of three dimensional polymer photonic crystal structures using single diffraction element interference lithography,” Applied Physics Letters, Volume 82, Mar. 17, 2003, 1667.

US 2007/0000536 by Yi, et al., published Jan. 4, 2007, entitled “Light trapping in thin film solar cells using textured photonic crystal,” discloses solar cell includes a photoactive region that receives light. A photonic crystal is coupled to the photoactive region, wherein the photonic crystal comprises a distributed Bragg reflector (DBR) for trapping the light.

### BRIEF SUMMARY OF THE DISCLOSURE OF THE INVENTION

The following brief summary is not intended to include all features and aspects of the present invention, nor does it imply that the invention must include all features and aspects discussed in this summary.

The present invention, in certain aspects, comprises a photovoltaic device, which utilizes photonic crystal design. It has an array of periodic dielectric structures providing a photonic crystal band gap structure allowing reflection, reception and transmission of incident light within specified wavelength ranges. This is a known property of photonic crystals, but in this case is applied to control incoming sunlight. That is, a photonic crystal has these properties, due to a periodic structure, having regions of high refractive index and low refractive index. Photons react to the refractive index contrast in an analogous manner to the way electrons react when confronted with a periodic potential of ions. Each results in a range of allowed energies and a band structure characterized by an energy gap or photonic band gap. Thus, in certain aspects, the desired wavelength range of the device is between 300 and 700 nm. Thus the periodic structure will be relatively small. The photonic structure will have a forbidden bandgap, and a transmissive mode. A wave-guide is used for directing said incident light of a certain wavelength forbidden in the structure but within the array to a photovoltaic region within the array. The photovoltaic region comprises a periodic array of dielectric structures comprising a pn junction for producing charges from the light of that certain wavelength from the wave-guide.

By utilizing an essentially regular structure, the present device incorporates both photovoltaic and photonic structures into a single unit. The photonic crystal with photovoltaic capability may be made by semiconductor processing techniques. It may be etched from a crystalline silicon wafer, and the photovoltaic material may be doped silicon rods. The silicon rods may be made photovoltaic by doping each with p- and n-type materials.

In certain aspects, the present invention employs a design where the photonic crystal is a 2-D array of nanorods formed on a substrate in a defined pattern. In order to form a photonic wave-guide, the repeating dielectric pattern is different as between the wave-guide and the photonic crystal bandgap structure. Multiple wave-guides of different transmissive modes for different incoming light wavelength ranges may be employed, each range matched to a wavelength activating a photovoltaic element. The wave-guide may be configured in a variety of ways, including extending the wave-guide to the surface of the crystal where it receives incoming wavelengths without reflection by the remaining crystal regions. The wave-guide may be of a funnel or convergent lens shape. The device may also be constructed to employ an external wave-guide for directing incoming light of different wavelengths to the multiple wave-guides. Multiple photonic crystals may be fabricated, either coplanar or stacked. The stacked array relies on the transmissive properties of the upper cell and photonic crystal. Different transmissive modes may be obtained by varying the dielectric structures, such as by varying at least one of the spacing of the pillars or the material in the pillars.

Because of the high efficiency of collection and the concentration of light in the photovoltaic region, in certain embodiments, the photovoltaic regions together may comprise less than ⅓ of the area for reception of incoming light. This allows more area for light collection. In certain embodiments, the photonic crystal is a 3-D photonic crystal, which can be made, e.g., by assembling various layers of dielectric spheres. In certain aspects, the present invention comprises a 2-D crystal where the photovoltaic region consists essentially of silicon pillars. The silicon pillars may be silicon cores surrounded in at least an upper or a lower region by CdTe.

The present device may be made by existing semiconductor fabrication techniques, such as photolithography, etching, etc. In certain aspects, the present invention comprises a method of making a photovoltaic device, comprising the steps of forming an array of periodic dielectric structures on a planar substrate, said structures comprising structures which are axially essentially parallel, of the same diameter and radially spaced in a regular array in a first region, to form a first photonic bandgap in a first, reflective region, but forming a second bandgap in a second, wave-guide region; doping a region of said rods adjacent to the wave-guide region to form pn junctions in a photovoltaic region; and forming electrical connections to the p and n regions.

As mentioned in connection with the device, the method may comprise the fabrication of multiple wave-guide regions adjacent a photovoltaic region. Rods or holes with different spacings may be prepared simultaneously, or certain rods may be removed after fabrication. Etching and lithography may also be used to define holes in a solid substrate to form the repeating dielectric pattern. The dielectric structures may semiconductor materials, as well as using air. The dielectric structures may also be selected from the group consisting of Si, CdTe, In1-xGalN, and CdSe.

### BRIEF DESCRIPTION OF THE DRAWINGS

FIG. 1 is a schematic drawing showing a hybrid photonic crystal/nano-solar cell according to one embodiment of the present invention.

FIG. 2 is a schematic of the device of FIG. 1 further comprising an external wave-guide and beam splitter.

FIG. 3 is a schematic illustration of pillars in a photonic crystal, with a gap defect and a core-shell type of p-n doping.

FIG. 4 is a schematic illustration of the wave-guide and photovoltaic cavity as enclosed within the photonic crystal material.

FIG. 5 is a schematic illustration of a planar multi-gap solar cell device, with off-the-shelf filters on top of the nanomaterials-based hybrid cells to further improve performance.

### DETAILED DESCRIPTION OF THE PREFERRED EMBODIMENT

### Overview

Described below is a new, self-focusing, highly efficient solar cell. The solar cell is self-focusing in that it utilizes the known property of photonic crystals to propagate light in any direction, provided that the light is within a transmissible band. This property is exploited here to also make the device more efficient by concentrating incoming light into a photovoltaic region (which generally is not formed of a material which is efficiently transmissive of light). The solar cell is, more generally, a photovoltaic cell, that is, it converts light energy into electrical energy. The light energy which is utilized by the present device is preferably in the wavelength region of solar energy, i.e., visible light, wavelength between 400 and 780 nanometers, ultraviolet light 160 and 400 nanometers. Light between 780 and 1,500 nanometers is known as infrared rays and carries lower levels of energy than visible sunlight. The visible violet light has a wavelength of about 400 nm. The visible violet light has a wavelength of about 400 nm. These wavelengths are selectively transmitted through the photonic crystal to the photovoltaic region.

The energy of the incoming radiation is related to its wavelength. Solar radiation has usable energy in the photon range of 0.4-4 eV. Light with energy below the bandgap of the photovoltaic material (that is, the semiconductor material in the photovoltaic region, shown for example as pillars) will not be absorbed and thus not be converted. Light with energy above the bandgap will be absorbed, but the excess energy above the bandgap will be lost in the form of heat.

The present device utilizes principles of photonic crystals, which can be fabricated to function as a wave guide as well as be made to have photovoltaic properties, to make improved use of the incoming light energy. When light from the sun propagates through the permissive modes of the wave-guides and into the optically confined cavity, the photon energy absorbed by the full device will be absorbed entirely by the photovoltaic material as opposed to the full photonic crystal.

In the present photonic crystal, photons (behaving as waves) propagate through the structure—or not—depending on their wavelength. Wavelengths of light (stream of photons) that are allowed to travel are known as modes, and groups of allowed modes form bands. Disallowed bands of wavelengths are called photonic band gaps. Further description on this aspect may be found, e.g., at Krauss T F, DeLaRue R M, Brand S “Two-dimensional photonic-bandgap structures operating at near infrared wavelengths” NATURE vol. 383 pp. 699-702 (1996). The transmissive portion of the photonic crystal region may be designed as described, e.g., in Leonard et al., “Single-mode transmission in two-dimensional macroporous silicon photonic crystal wave-guides,” OPTICS LETTERS/Vol. 25, No. 20/Oct. 15, 2000. As discussed there, if a linear defect is incorporated into a crystal, propagating modes confined within the defect can be created for frequencies within the photonic bandgap. A defect can therefore act as a wave-guide, with the confinement achieved by means of the photonic bandgap and not by total internal reflection as in traditional wave-guides. For example, in this case, for infrared work, lithography and alkaline etching were used to create pore nuclei in n-type silicon that were arranged in a two-dimensional triangular lattice with pitch of 1.5 mm. Although the pitch in the present device may be less, such dimensional control is within known semiconductor processing techniques. Similarly, a photonic cavity (see, e.g. 106a) can be created that is reflective at the bandgap and has photovoltaic capability.

The photovoltaic materials used in the present device need only occupy a portion of the device, which is connected to the wave-guide. One or more wave-guides may be used to direct light to the photovoltaic region from the absorptive and transmissive region. The photovoltaic region is contained in an optical cavity formed within the photonic crystal region. This cavity comprises only a fraction, e.g., less than 10-33%, of the area of the light-absorbing region. The photovoltaic (“PV”) material is tuned to absorb at the wavelength(s) that are transmitted through the wave-guide. This can be done using doped silicon rods. The rods may be core shell, or vertically stacked. The amount of and nature of the p- and n-materials may be determined according to known principles. Crystalline silicon has a bandgap energy of 1.1 electron-volts (eV). (An electron-volt is equal to the energy gained by an electron when it passes through a potential of 1 volt in a vacuum.) The bandgap energies of other effective PV semiconductors range from 1.0 to 1.6 eV. Typically, for example, Phosphorus atoms, which have five valence electrons, are used in doping n-type silicon, because phosphorus provides its fifth free electron. A phosphorus atom occupies the same place in the crystal lattice formerly occupied by the silicon atom it replaced. Boron, which has only three valence electrons, may be used for doping p-type silicon. For other energy ranges, one may use gallium arsenide, which absorbs at about 1.43 eV, or Aluminum gallium arsenide, which absorbs at about 1.7 eV. For hydrogenated amorphous silicon the photovoltaic band gap is 1.57 eV at 1-sun illumination. Solar cells can be made from alloys made from elements from Group III of the periodic table, like aluminum, gallium, and indium, or with elements from Group V, like nitrogen and arsenic.

The concentration of light through the wave-guide into the photovoltaic and optical cavity results in an increase in the absorption efficiency, which can both increase the performance of the solar cell conversion efficiency and overcome current thickness limits. It is possible therefore, using this construct, to make absorbing materials with the most suitable absorption coefficient for the central cavity region (the region that causes the appropriate complementary defect in the photonic crystal to match the absorption coefficient).

Furthermore, one can build a broad-band (or multi-gap) solar cell with this device by changing the material used for photovoltaic region to tune its absorption, and concomitantly changing the spacing in the photonic crystal to match that absorption shift. The result could be either a vertically layered structure or a planar structure.

The present solar cell is characterized by incorporation of a photonic crystal within the body of the photovoltaic material. The photonic crystal focuses light at high intensity and in a narrow wavelength region into a specific region of the crystal. This region is composed of photovoltaic material. An important aspect of the present device is that it can operate in the wavelength region of about 300-800 nm and, therefore, the lattice structure and the photonic crystal cavity where the light is concentrated for conversion to electricity must be on the order of nanometers in size.

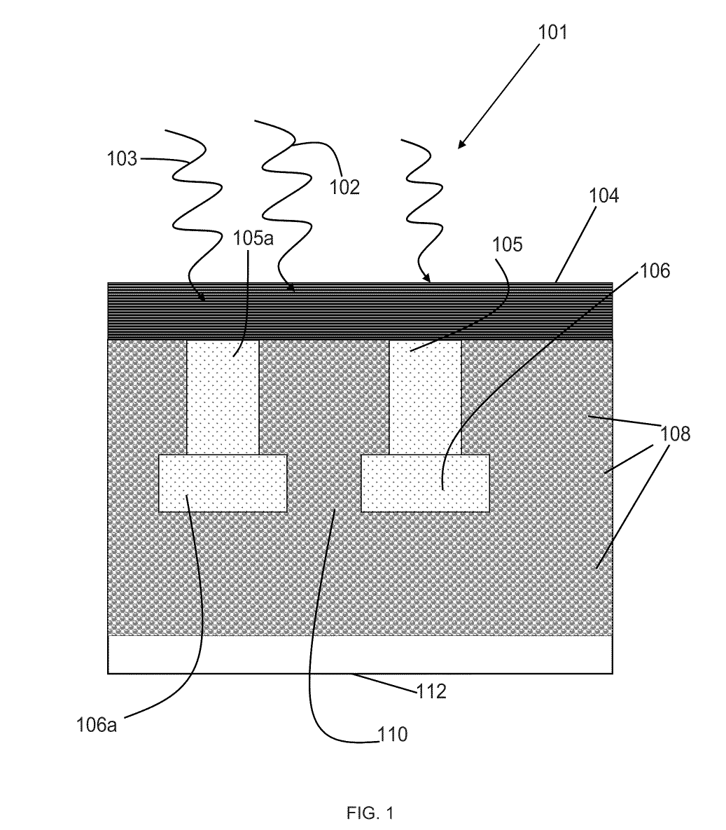

In order to design the proper spacing between pillars in a 2-D photonic crystal, one designs a proper band structure for the transmissive region and the wave-guide. The wave-guide is essentially a defect in the crystal that supports a mode that is in the band gap. This mode is forbidden from propagating in the bulk crystal because of the band gap. (That is, wave-guides operate in a manner similar to resonant cavities, except that they are line defects rather than point defects.) In FIG. 1, we see the dispersion relation for the guided mode created in a 2d photonic crystal (square lattice of rods) by removing a row of rods. When a bend is created in the wave-guide, it is impossible for light to escape (since it cannot propagate in the bulk crystal). The only possible problem is that of reflection. However, the problem can be analyzed in a manner similar to one-dimensional resonant tunneling in quantum mechanics, and it turns out to be possible to get 100% transmission.

Photonic crystals are described exactly by Maxwell's Equations, which can be solved by the application of massive computational power. A number of approaches to designing photonic crystals are known. One is described in Englund et al., “General recipe for designing photonic crystal cavities,” Optics Express, 13:5961-5975 (2005). Other approaches are described in Chapter 10 of Photonic Crystals: Modeling the Flow of Light, by Joannapoulos et al., 2007 available on line at ab-initio.mit.edu/book/photonic-crystals-book.pdf. To engineer the location and size of the bandgap, one may use computational modeling using any of the following methods: the plane wave expansion method, a finite difference time domain method, an order-N spectral method and the KKR method.

### Overall Device Construction (FIGS. 1 & 2)

A preferred embodiment of the present device is generally illustrated in FIG. 1. A solar cell 101 is designed to receive incident solar energy (light) 102 103 through a surface coating 104, which may be, e.g., ITO. Indium tin oxide (ITO) is electrically conductive and transparent in the near-IR to UV range (300 nm to >2600 nm). The light incident surface may be any transparent material, and may comprise a grid used as an electrode. The surface layer 104 may be designed to guide light to a wave-guide 105, 105a. Light 103, which has a frequency within a transmissive mode transmissive mode of a wave-guide 105, will be propagated. Light 102, which is in the band gap of the crystal layer 110, will not be transmitted.

Immediately below the surface coating 104 is a photonic crystal layer 110, into which one or more wave guides and photovoltaic regions are formed. This layer is formed as an ordered crystal at photonic dimensions, which, as is known, takes the form of periodic holes placed in a solid, transparent dielectric material, or pillars, or ordered arrays of spheres 108. Wavelengths outside of a band gap are transmitted. Photons moving through the crystal layer 110 of a transmissive wavelength are not guided to the photovoltaic cavities 106, 106a, but may be transmitted to a second photonic crystal wave-guide below the illustrated structure. In addition, different wave-guides 105, 105a may be transmissive for different wavelengths of sunlight that are in the band gap of the crystal region 110 and act to guide these wavelengths to the photovoltaic regions. Typically the crystal region 110 and the wave-guide regions 105, 105a will contain pillars and/or air holes arranged in a lattice pattern, will pass through regions of high refractive index, i.e., the dielectric, interspersed with regions of low refractive index, the air holes. This contrast in refractive index is comparable to the periodic potential that an electron experiences traveling through a silicon crystal. If there is large contrast in refractive index between the two regions, then most of the light will be confined either within the dielectric material or the air holes. This confinement results in the formation of allowed energy regions separated by a forbidden region, namely the photonic band gap. Since the wavelength of the photons is inversely proportional to their energy, the patterned dielectric material will block light with wavelengths in the photonic band gap, while allowing other wavelengths to pass freely. The present crystal region 108 and wave-guides 105, 105a are constructed so that the photons pass through the surface coating 104 to a wave guide 105 and thence to photovoltaic regions 106, 106a, where a photonic crystal cavity is formed (See, Englund et al., “General recipe for designing photonic crystal cavities,” Optics Express, 13(16): 5961-5975 (2005)). The cavities 106, 106a are formed by introducing spaces in the lattice which form mirrors to confine at least a portion of the wave-guide mode.

For purposes of illustration, two defect regions, 105, 105a and 106, 106a are shown. As shown, a defect region comprises a region 105a which communicates with the transparent electrode 104 and extends into the crystal layer 110 and further communicates with a defect region 106a arranged to extend further in a different direction (shown as orthogonal) to the defect region 105a and acting as a further wave guide or wave guide cavity. In practice, many such regions as 105, 106, 105a, 106a may be present. Each region may be constructed to absorb a wavelength of high energy content in sunlight. The maximum intensity of the emitted solar energy occurs at a wavelength of about 555 nm, which falls within the band of green light.

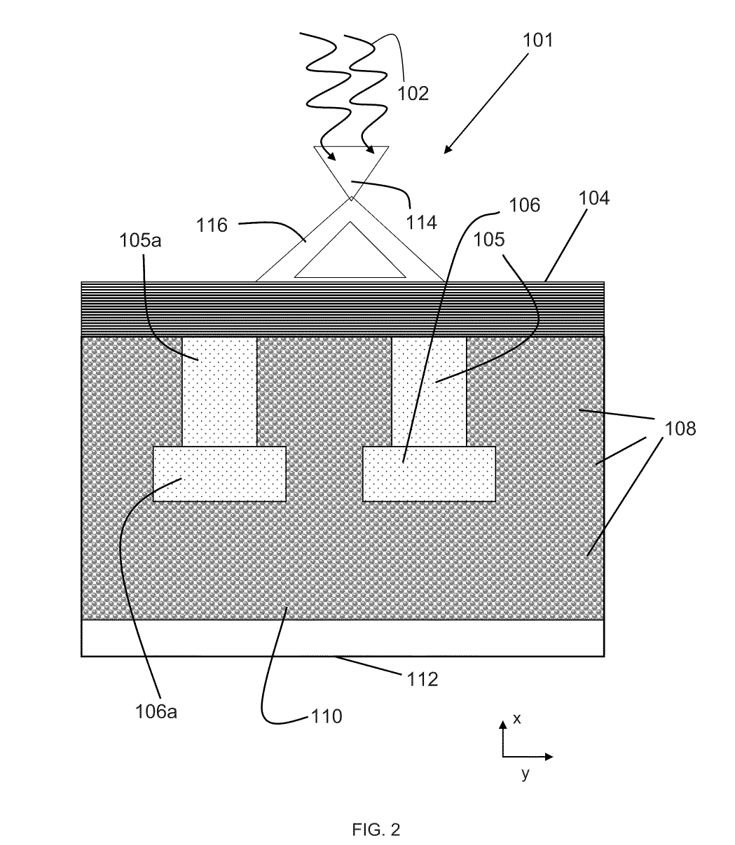

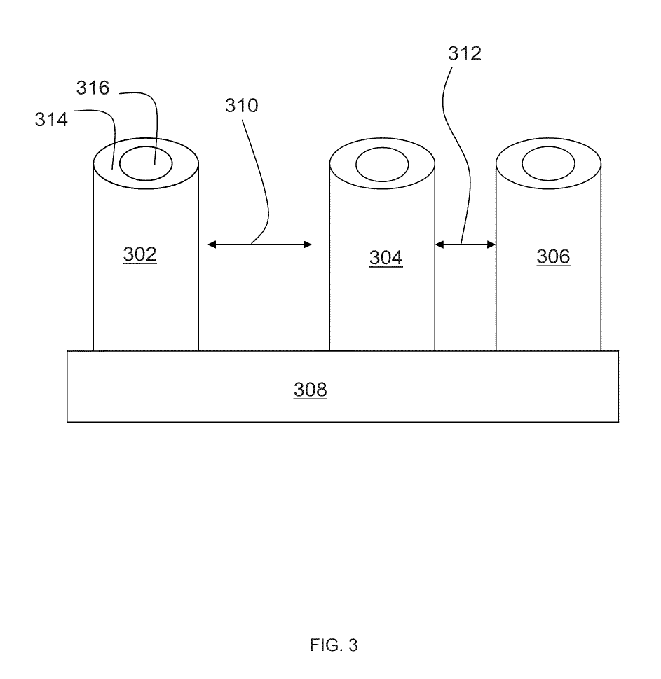

The photonic crystalline material 110 (FIG. 1) contains holes, pillars, or spheres 108. So-called “rods” or “pillars” run parallel to the holes and in between them, as further shown in FIG. 3. This is termed a 2-D photonic crystal in that the regular repeating pattern extends in 2 dimensions, x and y in FIG. 2. In the Z direction, there is no repetitive interference. However, it should be understood that 3-D photonic crystals can be constructed and adapted to the present teachings. At present, for ease of manufacturing it is preferable to use a 2D crystal, periodic in the distances between holes, that is, from top to bottom and left to right in FIG. 1. That permits the use of rods, which would extend into the plane of FIG. 1, that is, along the z axis, the x and y axes being illustrated. Again for ease of manufacture, the rods may be created on a nanoscale in order to interact with light in the visible range. The rods forming the wave-guide, the optical cavity and the photovoltaic region can be made on the same substrate, during a single series of steps, by varying the pitch between rods, and by applying photovoltaic material in the photovoltaic region.

In some embodiments, the photovoltaic region 106 may also act as a photonic crystal. As taught, e.g., in U.S. Pat. No. 6,931,191, issued Aug. 16, 2005 to Kitagawa et al., one may use high dielectric materials as photonic crystal members. The dielectric members may be formed of a material selected from the group consisting of Si, GaP, GaAs, InP, and ZnTe. Since-these materials have a high dielectric constant, and are easily made conductive by ion doping, the dielectric members can double as electrodes. This device is directed to varying the dielectric constant, and uses electricity rather than generating it.

The present dielectric members or the holes are arranged with a period corresponding to a specific optical wavelength.

As further shown in FIG. 1, the wave-guide and optical cavity, which is also a photovoltaic region, are regions of pillars and holes which are modified with so-called photonic crystal defects, which may be differences in size of surface properties, or different dielectric properties, etc., affecting photon propagation through the crystal. See, for further details, U.S. Pat. No. 6,674,949 to Allan, et al., issued Jan. 6, 2004, entitled “Active photonic crystal wave-guide device and method.” As explained there, the propagation of optical signals in photonic crystals is determined by a variety of parameters, including, for example, radius of the columns, pitch (center-to-center spacing of the columns) of the photonic crystal, structural symmetry of the crystal (e.g., square, triangular, hexagonal, rectangular), and refractive indexes, (such as the index of the material of the columns and the index of the bulk material exterior to the columns). Thus the photonic band gap is determined by the structure of the photonic crystal, especially by the parameters listed above. A defect can be introduced into the crystalline structure for altering the propagation characteristics and localizing the allowed modes for an optical signal. For example, as shown in the '949 patent, a two-dimensional photonic crystal may be made from a dielectric bulk material with a square lattice of air-filled columns and a linear defect consisting of a row of missing air-filled columns. The band diagram for this photonic crystal structure is also shown.

The wave-guide defect regions in the present device, illustrated at 105, 105a extend from the layer receiving the light (adjacent the transparent electrode (ITO) or collimating layer 104) into the body of the crystal and communicates with another defect region 106, 106a further into the crystal. Defect regions 106, 106a are designed to have a volume, such that photons guided to the area contact a large number of pillars within the region 106, which is photovoltaic, typically by virtue of the pillars containing p- and n-materials.

Referring now again to FIG. 1, bottom electrode 112 may also serve as an internal reflecting layer and may be connected by a conducting region (not shown) to the photovoltaic region. Alternatively, connections to electrodes may be provided at the ends of the pillars.

The photovoltaic defect region 106 is fabricated along with the rest of the photonic crystal, which acts as a matrix enveloping the photovoltaic region. The electrons generated in the photovoltaic region are conducted to electrodes at the ends of the pillars. The location of the electrodes will be based on the design of the photovoltaic region. One electrode will be attached to the p region(s) and one to the n region(s). If the rods are arranged in a parallel array, as shown for example in FIG. 3, one may dope a top portion of each photovoltaic rod with either a p- or n-material and place the electrodes on the top or bottom. If the pillars are a core and shell type of structure as illustrated there, one region may be formed to extend above the other, that is, the core does not extend to the bottom and extends above the shell. Alternatively, the substrate may be patterned to allow electrode connections to the external and internal structures.

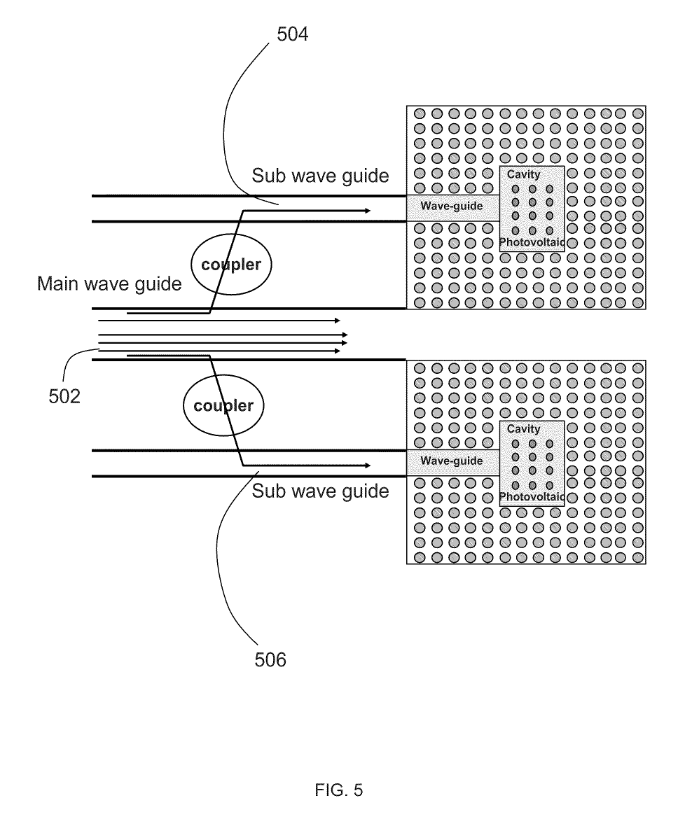

In another embodiment, illustrated in FIG. 2, a number of wave guides, illustrated at 116, receive incoming sunlight through a lens 114 and each wave guide direct the light to a different defect region 105, 105a. Here, incoming light 102 strikes a wave-guide, which is external to the photonic crystal. The wave-guide may be as shown in FIG. 5, or may be any kind of lens or prism. The lens 114 directs incoming light to the wave-guides, through guides 116, which may be of conventional structure, e.g., fiber optics. By using an external lens and light channels, the photonic crystal area may be diminished.

### Wave Guide (FIG. 3)

As described above, by creating a defect in an ordered 2-D crystal, the photonic crystal can act as a wave-guide 105, 105a, which focuses light at high intensity and narrow energy window onto a specific region of the crystal, namely photovoltaic cavity 106, 106a. If the defect is a modification of the crystal itself, for example by adding an extra layer or functional group to the edge of the pillars in that region, then the defect region could be engineered to be a nanoscale solar cell. Thus, the hybrid device employs the physics of photonic crystals by actually making part of the device itself into a working solar cell. If the spacing between the pillars is set correctly, and the material and geometry are chosen properly, then the solar cell (cavity or defect region) can be tailored to efficiently absorb precisely the light, which the photonic crystal is focusing into that region. A schematic of this concept is shown in FIG. 3.

As illustrated in FIG. 3, a series of pillars 302, 304 and 306 are attached to a substrate 308, which would be underneath the pillars illustrated in FIGS. 1 and 2. Light is propagated along the line of arrows 310 and 312. As can be seen by arrows 310 and 312, the distance between pillars 302 and 304 is greater than the distance between pillars 304 and 306. This constitutes a defect in the photonic crystal. This distance may also represent the size of holes. Light of a wavelength permitted by periodicity represented by distance 312 would be blocked at 302.

A rough estimate of the proper spacing between the holes or pillars (or the lattice size), e.g., distance 312, is given by the wavelength of the light divided by the refractive index of the dielectric material. It is more favorable for a photonic band gap to form in dielectrics with a high refractive index, which reduces the size of the lattice spacing even further. For example, to create a photonic crystal that could trap near-infrared light with a wavelength of 1 μm in a material with a refractive index of 3.0 one would have to create a structure in which the air holes were separated by about 0.3 μm.

By increasing the distance to 310 (such as removing a pillar), a linear defect is created in the crystal, which supports a mode that is in the band gap. This mode is forbidden from propagating in the bulk crystal because of the band gap. The present wave-guides are shown as linear. However, they may be bent or tapered. When a bend is created in the wave-guide, it is impossible for light to escape (since it cannot propagate in the bulk crystal). The only possible problem is that of reflection. However, the problem can be analyzed in a manner similar to one-dimensional resonant tunneling in quantum mechanics, and it turns out to be possible to get 100% transmission. There may also be more than one wave-guide connecting to a photovoltaic region, which, as started above, is preferably in an optical cavity.

Also illustrated in FIG. 3 is a core/shell structure in which a photovoltaic pillar contains an outer material 314, which is different from the inner, or core material 316. This design can be used to create photovoltaic properties in the rods, as discussed below. The outer material 314 may be an “n” material and the inner core, a “p” material. Thus, again, as discussed below, there is formed a junction of these two dissimilar semiconducting materials, one of which has a tendency to give up electrons and acquire holes (thereby becoming the positive, or p-type, charge carrier) while the other accepts electrons (becoming the negative, or n-type, carrier). The electronic structure that permits this is the band gap, which is tuned to the optical cavity and waveguide transmissive mode.

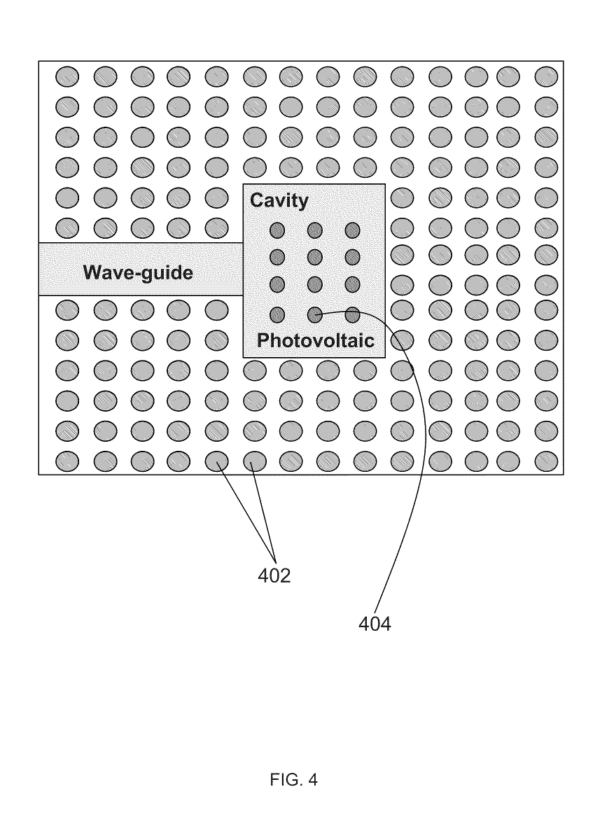

### Photovoltaic Cavity (FIG. 4)

FIG. 4 represents a detailed view, further illustrating the role of elements 105, 106, shown in FIG. 1. In this embodiment, the wave guide 105 and photovoltaic cavity 106 are within a matrix having holes equivalent to holes 108, as shown in FIGS. 1 and 2. Pillars 402 in the matrix region surrounding the photovoltaic cavity are not photovoltaic, but pillars 404 within the photovoltaic cavity are photovoltaic. The photovoltaic cavity, as in other embodiments is surrounded completely in two dimensions by the photonic crystal array, including the wave guide. The photonic crystal region may also surround the photovoltaic cavity above and below, provided that accommodation is made for electrodes from the photovoltaic elements.

Thus, the present nanoscale solar cell comprises photovoltaic (“PV”) elements, i.e., it comprises comprise two separate layers of materials, one with an abundance of electrons that functions as a “negative pole,” and one with an abundance of electron holes (vacant, positively-charged energy spaces) that functions as a “positive pole.” When photons from the sun or some other light source are absorbed, their energy is transferred to the extra electrons in the negative pole, causing them to flow to the positive pole and creating new holes that start flowing to the negative pole.

In the presently preferred embodiment, semiconductor manufacturing techniques are used to make the necessary pillars and holes, and to deposit the desired materials. Thus, the present device is preferably constructed of crystalline silicon material. Single-crystal silicon cells are the most common in the photovoltaic industry. Consisting of small grains of single-crystal silicon, polycrystalline PV cells are less energy efficient than single-crystalline silicon PV cells. A compound semiconductor made of two elements: gallium (Ga) and arsenic (As), GaAs has a crystal structure similar to that of silicon. An advantage of GaAs is that it has high level of light absorptivity.

While the present device is based on principles of crystal lattices, thin film materials can be used due to the small scale of the device. Since the wavelength of concern here is about 780-1500 nm, the spacings between features will be on the order of 1-3 times this distance, i.e., about 780 4500 nm. Thus, one may use the above described repeating lattices and defects forming wave-guides and photovoltaic cavities in a thin-film photovoltaic cell. In this case, a thin semiconductor layer of PV materials is deposited on low-cost supporting layer such as glass, metal or plastic foil. Since thin-film materials have higher light absorptivity than crystalline materials, the deposited layer of PV materials is extremely thin, from a few micrometers to even less than a micrometer (a single amorphous cell can be as thin as 0.3 micrometers). Amorphous silicon is a non-crystalline form of silicon i.e., its silicon atoms are disordered in structure. A significant advantage of amorphous Si is its high light absorptivity. As a polycrystalline semiconductor compound made of cadmium and tellurium, CdTe has a high light absorptivity level—only about a micrometer thick can absorb 90% of the solar spectrum. Another material of interest is a polycrystalline semiconductor compound of copper, indium and selenium, CIS. CIS is also one of the most light-absorbent semiconductors—0.5 micrometers can absorb 90% of the solar spectrum. Another embodiment utilizes thin-film CIGS-(Copper, Indium, Gallium, and Selenium) materials. These materials use a thin film is a process where material from a target source is coated onto a substrate via a plasma field. These thin films are only angstroms to microns thick.

Another suitable material is an In1-xGaxN ternary alloy system extended over a very wide energy range (0.7 eV to 3.4 eV), which will provide a near-perfect match to the solar energy spectrum.

More details may be found in J. Wu, W. Walukiewicz, K. M. Yu, J. W. Ager III, E. E. Haller, H. Lu, W. J. Schaff, Y. Saito, and Y. Nanishi, “Unusual properties of the fundamental band gap of InN,” Appl. Phys Lett., 80, 3967-3969 (2002).

Photonic crystals have been formed in organic matrices. See, e.g., Pisigano et al., “Planar organic photonic crystals fabricated by soft lithography,” Nanotechnology, Volume 15, Number 7, July 2004, pp. 766-770(5), and Duche et al., “Slow Bloch modes for enhancing the absorption of light in thin films for photovoltaic cells,” Appl. Phys. Lett., 92, 193310 (May, 2008). The latter publication describes a theoretical study using a poly-3-hexylthiophene/[6,6]-phenyl-C61-butyric acid methyl ester (P3HT/PCBM) thin film periodically nanostructured in order to increase its absorption. The periodic nanostructuration allows “slow Bloch modes” (group velocity close to zero) to be coupled inside the material. The P3HT/PCBM photonic crystal parameters are adjusted to maximize the density of Bloch modes and obtain flat dispersion curves. The light-matter interaction is thus strongly enhanced, which results in a 35.6% increase of absorption in the 600-700 nm spectral range.

One may also use organic polymer based photovoltaic materials, such as described e.g., in Huynh et al., “Hybrid Nanorod-Polymer Solar Cells,” Science, 295:2425-2427 (29 Mar. 2002). As described there, a photovoltaic device consisting of 7-nanometer by 60-nanometer CdSe nanorods and the conjugated polymer poly-3(hexylthiophene) was assembled from solution with an external quantum efficiency of over 54% and a monochromatic power conversion efficiency of 6.9% under 0.1 milliwatt per square centimeter illumination at 515 nanometers. CdSe is electron-accepting and P3HT is hole-accepting. Because CdSe and P3HT have complementary absorption spectra in the visible range, these nanorod-polymer blend devices have a very broad photocurrent spectrum extending from 300 to 720 nm. Unlike other electron acceptors such as C60 in organic blend devices, and sintered TiO₂ in dye-sensitized solar cells, CdSe nanorods absorb a significant part of the solar spectrum. Furthermore, the absorption spectrum of the hybrid devices presented here can be tuned by altering the diameter of the nanorods in order to optimize the overlap with the solar emission spectrum.

Thus, the above-described nanorods may be used as the electron accepting positive pole. Other structures, which can be positive or negative poles, are silicon pillars, Si doped differently at its core and shell, e.g., a “p” rod inside an “n” rod, and other materials

### Multiple Wave Guides and Couplers (FIG. 5)

FIG. 5 illustrates schematically another embodiment of this device, where existing channel-drop filters can be used to separate different wavelengths of light in each of the corresponding cavities with suitable embedded photovoltaics to match the absorption frequency. Given a collection of signals propagating down a waveguide (called the bus waveguide), a channel-drop filter picks out one small wavelength range (channel) and reroutes (drops) it into another waveguide (called the drop waveguide). In FIG. 5, incoming sunlight of multiple wavelengths passes through a main wave-guide 502 which is shown in between two subwave guides, and which may or may not direct light into the crystal region (here it does not). The incoming multiple wavelengths are sorted into different, discrete wavelengths 504, 506 by the channel drop filter. Each wavelength has its own coupler tuned to the desired frequency and connected to its own photonic wave-guide. There are separate optical cavities for each frequency, as described above in connection with FIG. 2. Channel drop filters are commercially available and are further described in U.S. Pat. No. 4,673,270, issued Jun. 16, 1987.

FIG. 5 also illustrates the idea that the present device may be composed of two different photonic crystals, with different crystal structures and different band gaps. One crystal can be tuned to one wavelength, and the other to another wavelength. Since wavelengths below the bandgap will pass through the crystal the second device may be placed below a first, higher energy material.

### CONCLUSION

The above specific description is meant to exemplify and illustrate the invention and should not be seen as limiting the scope of the invention, which is defined by the literal and equivalent scope of the appended claims. Any patents or publications mentioned in this specification are intended to convey details of methods and materials useful in carrying out certain aspects of the invention which may not be explicitly set out but which would be understood by workers in the field. Such patents or publications are hereby incorporated by reference to the same extent as if each was specifically and individually incorporated by reference, as needed for the purpose of describing and enabling the method or material referred to.

What is claimed is::

1. A photovoltaic device comprising:
a photonic crystal having an array of periodic dielectric structures providing a photonic crystal band gap structure allowing reflection, reception and transmission of incident light within at least one specified wavelength range; and
photonic wave-guide within the photonic crystal for directing said incident light of a certain wavelength within the array to a photovoltaic region within the photonic crystal,
said photovoltaic region comprising a periodic array of dielectric structures comprising at least one pn junction for producing charges from the light of the certain wavelength from the wave-guide.

2. The device of claim 1 wherein the photonic crystal is etched from a crystalline silicon wafer and the photovoltaic region comprises doped silicon rods.

3. The device of claim 1 wherein the silicon rods are doped with p and n materials,

4. The device of claim 1 wherein the specified wavelength range is between 300 and 700 nm.

5. The device of claim 1 wherein the photonic crystal comprises a two-dimensional array of nanorods formed on a substrate in a defined pattern.

6. The device of claim 5 wherein the pattern is different as between the wave-guide and the photonic crystal bandgap structure.

7. The device of claim 1 comprising multiple photonic crystals and multiple wave-guides of different transmissive modes for different incoming light wavelength ranges, each of such ranges matched to a wavelength activating a photovoltaic element, thereby activating multiple photovoltaic regions.

8. The device of claim 7 comprising an external wave-guide for directing incoming light of different wavelengths to the multiple wave-guides.

9. The device of claim 7 wherein the multiple photonic crystals are coplanar.

10. The device of claim 7 wherein the different transmissive modes are obtained by varying the spacing of the dielectric structures.

11. The device of claim 7 wherein the photovoltaic regions together comprise less than one-third of the area for reception of incoming light.

12. The device of claim 1 wherein the photonic crystal comprises a three-dimensional photonic crystal.

13. The device of claim 1 wherein the photovoltaic region consists essentially of silicon pillars.

14. The device of claim 13 where the silicon pillars comprise silicon cores surrounded in at least an upper or a lower region by CdTe.

15. A method of making a photovoltaic device, comprising:
(a) forming an array of periodic dielectric structures on a planar substrate, said structures comprising structures which are axially essentially parallel, of the same diameter and radially spaced in a regular array in a first region, to form a first photonic bandgap in a first, reflective region, but forming a second bandgap in a second, wave-guide region;
(b) doping a region of said structures adjacent to the wave-guide region to form pn junctions in a photovoltaic region; and
(c) forming electrical connections to the p and n regions.

16. The method of claim 15 further comprising forming multiple wave-guide regions adjacent a photovoltaic region.

17. The method of claim 15 wherein the structures formed in step (a) comprise rods.

18. The method of claim 15 wherein the dielectric structures comprise semiconductor materials.

19. The method of claim 15 wherein the dielectric structures are selected from the group consisting of Si, CdTe, In1-xGalN, and CdSe.

20. The device of claim 2 wherein the silicon rods are doped with p and n materials.

21. The device of claim 4 wherein the photonic crystal comprises a two-dimensional array of nanorods formed on a substrate in a defined pattern.

22. The device of claim 7 wherein the multiple photonic crystals are stacked.

23. The device of claim 8 wherein the multiple photonic crystals are coplanar.

24. The device of claim 8 wherein the multiple photonic crystals are stacked.

25. The device of claim 7 wherein the different transmissive modes are obtained by varying the material in the dielectric structures.

26. The device of claim 8 wherein the different transmissive modes are obtained by varying the spacing of the dielectric structures.

27. The device of claim 8 wherein the different transmissive modes are obtained by varying the material in the dielectric structures.

28. The device of claim 8 wherein the photovoltaic regions together comprise less than one-third of the area for reception of incoming light.

29. The device of claim 12 wherein the photovoltaic region consists essentially of silicon pillars.

30. The method of claim 15 wherein the structures formed in step (a) comprise holes.

31. The method of claim 16 wherein the structures formed in step (a) comprise rods.

32. The method of claim 16 wherein the structures formed in step (a) comprise holes.

33. The method of claim 16 wherein the dielectric structures comprise semiconductor materials.

34. The method of claim 16 wherein the dielectric structures are selected from the group consisting of Si, CdTe, In1-xGalN, and CdSe.
